(19) United States
(12) Patent Application Publication
(10) Pub. No.: US 2025/0096191 A1
(43) Pub. Date: Mar. 20, 2025

(54) DIRECT BONDING METHODS AND STRUCTURES FOR DIES

(71) Applicant: ADEIA SEMICONDUCTOR BONDING TECHNOLOGIES INC., San Jose, CA (US)

(72) Inventors: Guilian Gao, Campbell, CA (US); Gaius Gillman Fountain, JR., Youngsville, NC (US); Pawel Mrozek, San Jose, CA (US); Ron Zhang, Sunnyvale, CA (US); Laura Wills Mirkarimi, Sunol, CA (US)

(21) Appl. No.: 18/503,127

(22) Filed: Nov. 6, 2023

Related U.S. Application Data
(60) Provisional application No. 63/583,554, filed on Sep. 18, 2023.

(51) Int. Cl. H01L 23/00; H01L 21/78; H01L 23/31

(52) U.S. Cl. CPC H01L 24/80; H01L 21/78; H01L 23/3107; H01L 24/08; H01L 2224/08145; H01L 2224/80895; H01L 2224/80896

(57) ABSTRACT

Disclosed herein are methods of forming a microelectronic device. In some embodiments, the methods include preparing a first surface of a first substrate for direct bonding and thinning the first substrate to form a thinned substrate, where the thinned substrate comprises the first surface and a second surface and where the first and second surfaces are on opposing sides of the thinned substrate. The method further includes, after thinning, depositing a stress balancing layer onto the second surface, singulating the thinned substrate to form a plurality of dies, and direct bonding at least one of the plurality of dies to a second substrate.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 157.

This application claims the benefit under 35 U.S.C. § 119 (e) to U.S. Provisional Application No. 63/583,554, entitled “DIRECT BONDING METHODS AND STRUCTURES FOR DIES,” filed Sep. 18, 2023, the entirety of which is hereby incorporated by reference herein.

### BACKGROUND

### Field

The field relates to direct bonding methods and structures.

### Description of the Related Art

Microelectronic elements, such as integrated device dies or chips, may be mounted or stacked on other elements thereby forming a bonded structure. Direct bonding can be conducted at low temperatures and without external pressure. For example, hybrid bonding involves directly bonding non-conductive features (e.g., inorganic dielectrics) of different elements together, without intervening adhesives, while also directly bonding conductive features (e.g., metal pads or lines) of the elements together. For example, a microelectronic element can be mounted to a carrier, such as a wafer, an interposer, a reconstituted wafer or other element, etc. As another example, a microelectronic element can be stacked on top of another microelectronic element, e.g., a first integrated device die can be stacked on a second integrated device die. Each of the microelectronic elements can have conductive pads for mechanically and electrically bonding the elements to one another. There is a continuing need for improved methods for forming bonded structures.

### BRIEF DESCRIPTION OF THE DRAWINGS

FIG. 1A is a schematic side sectional view of two elements before being directly bonded, according to an embodiment.

FIG. 1B is a schematic side sectional view of the two elements of FIG. 1A after being directly bonded, according to an embodiment.

FIGS. 2A and 2B are schematic side sectional views of bonded structures having stress balancing layers formed on backsides of the dies, according to embodiments.

FIG. 3 is a flowchart illustrating a process of forming a bonded structure that includes dies having stress balancing layers formed on their back sides, according to some embodiments.

FIGS. 4A-4E are schematic side sectional views of elements at various stages of a process like that of FIG. 3.

FIG. 5 is a schematic side sectional view of a bonded structure having multiple dies bonded to an element, according to some embodiments.

FIG. 6 is a schematic side sectional view of a bonded structure having a reconstitution layer, according to some embodiments.

FIG. 7 is a schematic side sectional view of a bowed microelectronic element.

FIG. 8 is a flowchart illustrating a process of forming a bonded structure that includes dies having a stress balancing layer formed on a back side, according to some embodiments.

FIGS. 9A-9C are graphs illustrating the relationship between die warpage and bondability.

FIG. 10 is a flowchart illustrating a process of forming a bonded structure that includes dies having a stress balancing layer formed on a back side, according to some embodiments.

FIGS. 11A and 11B are a flowchart illustrating a process of forming a bonded structure that includes dies having a stress balancing layer formed on a back side, according to some embodiments.

### DETAILED DESCRIPTION OF THE PREFERRED EMBODIMENT

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surfaces or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

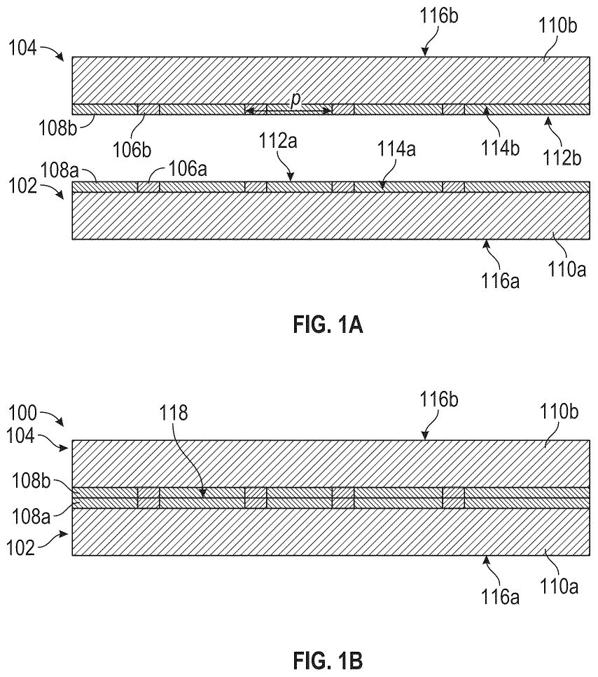

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a. 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms. 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

When bonding a die to a substrate, care must be taken to ensure that the quality and strength of the bond is sufficiently high, and the ability of a die to form a sufficiently high-quality and high-strength bond is known as the die's bondability. For dies bonded using conventional bonding techniques (e.g., flip chip bonding, soldering, processes that use adhesives, etc.), the bondability of a die is relatively tolerant to any die warpage and minor bowing because these bonding processes were more flexible and forgiving. However, direct bonding processes are significantly less forgiving and tolerant than the conventional bonding techniques. This means that, for direct bonding, the bondability of wafers and other large substrates can be very sensitive to warpage and bowing. Surprisingly, warpage and bowing can have significant effects even for bonding of dies, and even for relatively small dies. Additionally, the bondability of a die used in direct bonding processes is also related to the rigidity and stiffness of the die, and the relationship between the bondability of a die and the die's warpage, rigidity, and stiffness can be represented by Equation 1 below:

$$Bondability ∼ {C}_{1} \times Warpage + \frac{{C}_{2}}{Rigidity} + \frac{{C}_{3}}{Stiffness} + {C}_{4} \qquad [ 1 ]$$

where C₁, C₂, C₃, and C₄ are constant coefficients and C is negative. The rigidity of a die is related to the material that the die is formed from (e.g., the Young's modulus of the die material) as well as the die's overall thickness. The stiffness of the die is also related to the die material and thickness and is also related to the size (lateral dimensions) of the die. Equation 1 suggests that bondability is directly correlated with reduced warpage and inversely correlated with both rigidity and stiffness.

As described in greater detail elsewhere in the specification, the values of each of the constant coefficients C₁, C₂, C₃, and C₄ are different for each die size and can be determined experimentally. Experiments have determined that the die's warpage can have a significant effect on the die's bondability (i.e., the absolute value of C₁ for any particular elements to be bonded is greater than C₂ and C₃). Significantly, though, because embodiments described herein also account for the effect of rigidity and stiffness upon bondability, embodiments herein can improve bondability in a predictable way without excessive experimentation for each new bond structure configuration.

Warpage is measure of the amount that the bonding surface of an element deviates from a flat surface, suggesting that the quality and strength of a direct bond is highly dependent on the flatness of the surfaces being directly bonded together. This is because the strength and quality of a direct bond between two bonding surfaces is generally dependent on the contact area between the two bonding surfaces, and flatter bonding surfaces tend to result in greater contact area. Accordingly, the bondability of a microelectronic element is highly dependent on the flatness of its bonding surface. In other words, microelectronic elements (e.g., substrates, wafers, dies, interposers, etc.) having bonding surfaces that are not sufficiently flat (e.g., that are too bowed or warped) prior to direct bonding tend to have poor bondability because they tend to form weak and low-quality direct bonds. One of the primary causes of bowing and warping in a microelectronic element is an imbalance between the stresses on the front side of the element and the back side of the element. For example, the front side of a semiconductor element may include multiple insulators and layers with embedded metal (including BEOL layers) on top of bulk semiconductor material, whereas the backside of the bulk semiconductor may be bare or include significantly less other material, particularly after thinning. This imbalance of surface stresses can result in the microelectronic element having a low-stress state that is warped and bowed, which can result in the microelectronic element having poor bondability.

Conventionally, semiconductor processing has tended to focus on warpage issues at the panel or wafer level, prior to singulation into dies, since warpage for large substrates produces large absolute bow numbers compared to small dies. Additionally, traditional die bonding (e.g., flip chip bonding) often employs heating and/or external pressure, which would have tended to negate any warpage issues at the die bonding stage. However, direct bonding of dies can be more sensitive to flatness issues during bonding than more traditional forms of bonding, particular for bonding techniques that omit external pressure.

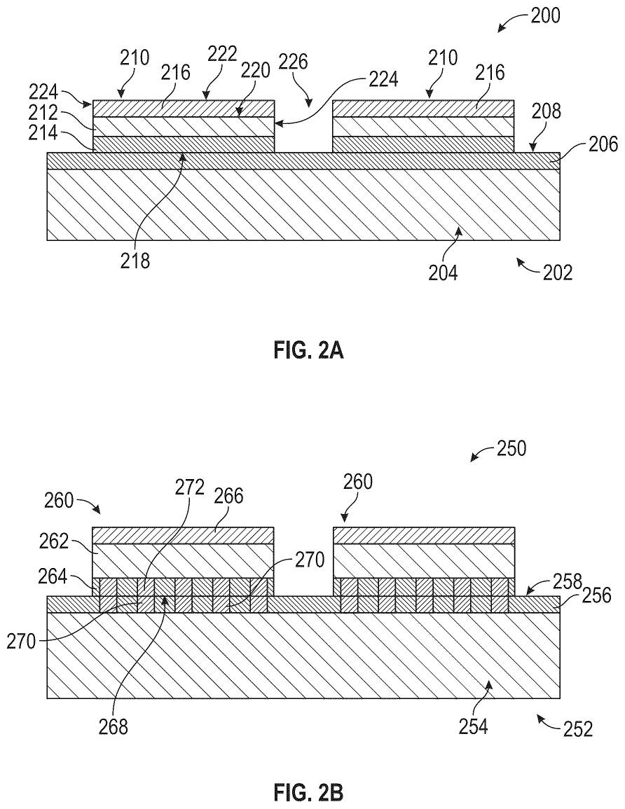

To address these challenges, a layer of a dielectric material can be deposited over a back surface of the microelectronic element, which can reduce or even eliminate the stress imbalances between the front and back sides of the microelectronic element. As discussed in greater detail elsewhere in this application, this layer of dielectric material, which can also be referred to as a stress balancing layer, can be formed over a pre-singulated element (e.g., a semiconductor wafer or a packaging substrate web or panel) prior to the element being singulated into dies and then directly bonded to a substrate to form a bonded structure. FIG. 2A illustrates a bonded structure 200 that includes a substrate 202 and one or more dies 210 directly bonded to the substrate 202, where each of the one or more dies has a stress balancing layer 216. The substrate 202 includes a substrate base portion 204 and a substrate bonding layer 206. The substrate bonding layer 206 can formed from a non-conductive or dielectric material and defines a substrate bonding surface 208. In some embodiments, the substrate bonding surface 208 comprises a non-conductive field region formed from the dielectric material. In some embodiments, the backside of the substrate 202 can also include a stress balancing layer (not shown). The dies 210 each include a die base portion 212, a die bonding layer 214, and the stress balancing layer 216, where the die bonding layer 214 and stress balancing layer 216 are on opposing sides of the die base portion 212. The die bonding layer 214 can be formed from a non-conductive or dielectric material and defines a die bonding surface 218 which, in some embodiments, comprises a non-conductive field region. The substrate bonding surface 208 and the die bonding surfaces 218 can be directly bonded together with a direct dielectric-to-dielectric bond without an intervening adhesive.

For semiconductor element examples, each of the substrate base portion 204 and the die base portions 212 can comprise bulk semiconductor materials, such as single crystal silicon, III-V materials (e.g., GaN, GaAs, etc.) or optical materials (LiTaO₃, LiNbO₃, etc.). Although not separately illustrated, the skilled artisan will appreciate that microelectronic elements can also include multiple BEOL layers at the front sides of the bonding elements 202, 210. Such BEOL layers can be considered to lie between the bonding layers 206, 214 and the base portions 204, 212, or can be considered to be part of the bonding layers or part of the base portions. Such BEOL layers can have considerable total thickness of dielectric materials and embedded metal lines and vias, thus contribute significantly to stresses at the front sides.

As discussed in greater detail elsewhere in the specification, the stress-balancing layer 216 is formed by depositing a non-conductive or dielectric material onto a back surface 220 of the die base portion 212. The stress balancing layer 216 defines a backside 222 of the dies 210. The dies 210 also include side surfaces 224 that extend between the die bonding surface 218 and the backside 222. In some embodiments, the die base portion 212 and die bonding layer 214 can have a total thickness of about 100 μm. In other embodiments, however, the die base portion 212 and die bonding layer 214 can have a different total thickness. For example, in some embodiments, the die base portion 212 and die bonding layer 214 can have a total thickness of about 2 μm, about 5 μm, about 10 μm, about 20 μm, about 30 μm, about 50 μm, about 100 μm, about 150 μm, about 180 μm, about 200 μm, about 240 μm, about 300 μm, or a thickness in a range defined by any of these values. In some embodiments, the die base portion 212 and die bonding layer 214 can have a total thickness between about 2 μm and about 300 μm, between about 2 μm and about 100 μm, between about 2 μm and about 50 μm, between about 5 μm and about 30 μm, between about 30 μm and about 100 μm, between about 100 μm and about 300 μm, or a thickness in a range defined by any of these values. In some embodiments, the dies 210 do not include a through-silicon via (TSV) or other backside conductors, such that the stress balancing layer 216 is formed on the back surface 220 of the die base portion 212 and is not formed over a conductive component of the die 210. The stress balancing layers 216 can thus be unpatterned.

As discussed in greater detail elsewhere in the specification, the stress balancing layer 216 is configured to balance internal stresses within the die 210 so that the die 210, and particularly the die bonding surface 218, remains sufficiently flat during bonding to permit high quality, reliable bonds, without large voids at the bond interface. Additionally, in some embodiments, the stress balancing layer can also reduce post-bonding stresses within the bonded dies, which can be helpful in ensuring that the die remains bonded to the substrate. Accordingly, the stress balancing layer 216 can have a thickness sufficient to cause the die 210 to stay sufficiently flat. For example, in some embodiments, the stress balancing layer 216 can have a thickness of about 5. In other embodiments, however, the stress balancing layer 216 can have a different thickness. For example, in some embodiments, the stress balancing layer 216 can have a thickness between about 0.5 μm and about 10 μm, between about 0.5 μm and about 1 μm, between about 0.5 μm and about 2 μm, about 0.5 μm and about 3 μm, about 0.5 μm and about 4 μm, about 0.5 μm and about 5 μm, about 1 μm and about 5 μm, about 2 μm and about 5 μm, about 5 μm and about 10 μm, or a thickness in a range defined by any of these ranges. As discussed in greater detail elsewhere in the application, in some embodiments, the thickness of the stress balancing layer 216 can be based at least in part on one or more of the thickness of the die 210, the dimensions of the die 210, the thickness and/or dimensions of the substrate from which the die 210 is formed, a measured bowing and/or warpage of the substrate from which the die 210 is formed, and a composition of the die 210. Significantly, the thickness of the stress balancing layer 216 is not selected simply to equal the thicknesses or stress of the front side bonding layer 214 and BEOL layers, but rather is selected to tune bondability by balancing multiple factors, as reflected by Equation 1 above. Advantageously, details of the composition elements being bonded need not be accounted for in calculating the thickness of the stress balancing layer 216 by techniques taught herein.

In some embodiments, the stress balancing layer 216 is formed from a dielectric material, such as an inorganic dielectric material. For example, in some embodiments, the stress balancing layer 216 can comprise any of the materials described above for bonding layer materials, including but not limited to inorganic dielectrics including silicon, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. Both the material composition and the manner of formation can affect the internal stress of the stress balancing layer 216 and thus affect the selected thickness for ensuring good bondability.

In some embodiments, as noted above, the stress balancing layer 216 comprises an unpatterned backside dielectric layer. In such embodiments, the stress balancing layer 216 does not include any conductive features formed on or within the stress balancing layer. For example, in some embodiments, the stress balancing layer does not include any conductive traces, interconnects, TSVs, bond pads, or other conductive features. In the illustrated embodiment, the stress balancing layer 216 is formed from a single layer of dielectric material. In other embodiments, however, the stress balancing layer 216 can be formed from multiple layers of dielectric material. For example, in some embodiments, the stress balancing layer 216 can be formed from multiple layers of the same type of dielectric material or one or more layers of different types of dielectric materials.

In the illustrated embodiment, the bonded structure 200 includes two dies 210 directly bonded to the substrate 202. In other embodiments, however, the bonded structure 200 can include a different number of dies 210. For example, in some embodiments, the bonded structure 200 can include a single die 210, can include three dies 210, or can include more than three dies 210. In some embodiments where the bonded structure 200 includes multiple dies 210, each of the dies 210 can include the stress balancing layer 216. In other embodiments, however, only some of the dies 210 can include the stress balancing layer 216. Additionally, in embodiments where multiple dies 210 have the stress balancing layer 216, the stress balancing layers 216 can have the same or different compositions and can have the same or different thicknesses, each of which can be calculated for the particular die composition and dimensions as described herein. In general, the composition and thickness of the stress balancing layers 216 can be independently selected for each die 210 to ensure that each die 210 remains sufficiently flat so that a good quality direct bond is formed between the individual dies 210 and the substrate 202.

The dies 210 are separated from each other by a lateral gap 226. In some embodiments, the lateral gap 226 is not filled with a material. In other embodiments, however, the lateral gap 226 is filled with a dielectric material. For example, in some embodiments, the bonded structure 200 includes a reconstitution layer formed over the dies 210. In these embodiments, at least part of the reconstitution layer at least partially fills the lateral gap 226. In embodiments where the lateral gap 226 is filled with a dielectric material, the lateral gap can be filled with a different dielectric material than the dielectric material that the stress balancing layer 216 is formed from. In some embodiments, the lateral gap 226 can be filled with organic encapsulation or mold material.

As discussed in greater detail elsewhere in the specification, the stress balancing layer 216 is formed prior to the die being singulated. For example, in some embodiments, the stress balancing layer 216 can be formed by depositing a dielectric material over a back surface of a substrate base portion and then singulating the substrate base portion and deposited dielectric material to form the die 210 having the stress balancing layer 216. Accordingly, the stress balancing layer 216 is confined to the footprint of the die 210 such that it does not extend beyond the edge of the back surface 220 of the die base portion 212 and such that it does not contact the side surfaces 224 of the dies 210. Additionally, the stress balancing layer 216 does not extend into the lateral gap 226 formed between the dies 210.

In the embodiment shown in FIG. 2A, the substrate bonding layer 206 and the die bonding layers 214 each comprise a dielectric material and do not include conductive features within the bonding layers 206, 214 such that the dies 210 are direct bonded to the substrate 202 with a direct dielectric-to-dielectric bond without an intervening adhesive. In other embodiments, however, the substrate bonding layer and the die bonding layers can each include one or more conductive features. In these embodiments, the dies can be directly bonded to the substrate with hybrid bonding, which generally involves opposing nonconductive surfaces being directly bonded without an intervening adhesive and opposing conductive features being directly bonded without an intervening adhesive. For example, FIG. 2B illustrates a bonded structure 250 that involves hybrid bonding. Unless otherwise noted, features of bonded structure 250, including but not limited to the compositions and features of the bonding layers, BEOL layer(s), base portions and stress balancing layers, may be generally similar to features of bonded structure 200.

The bonded structure 250 of FIG. 2B includes a substrate 252 and dies 260 directly bonded to the substrate 252. The substrate 252 includes a substrate base portion 254 and a substrate bonding layer 256. The substrate bonding layer 256 comprises a dielectric material and one or more conductive features 270 formed within the dielectric material. In some embodiments, the dielectric material at least partially surrounds the conductive features 270. The dielectric material and conductive features 270 define a substrate bonding surface 258 of the substrate 252 which, in some embodiments, includes a non-conductive field region formed from the dielectric portions of the substrate bonding surface 258 and also includes one or more conductive regions formed by the one or more conductive features 270. The dies 260 each include a die base portion 262, a die bonding layer 264, and a stress balancing layer 266, where the die bonding layer 264 and stress balancing layer 266 are formed on opposing sides of the die base portion 262. The die bonding layer 264 comprises a dielectric material and one or more conductive features 272 formed within the dielectric material. In some embodiments, the dielectric material at least partially surrounds the conductive features 272. The dielectric material and conductive features 272 define a die bonding surface 268 of the substrate 260 which, in some embodiments, includes a non-conductive field region formed from the dielectric portions of the die bonding surface 268 and also includes one or more conductive regions formed by the one or more conductive features 272.

The substrate 252 and the dies 260 can be directly bonded together with hybrid bonds that are formed between the substrate bonding surface 258 and the die bonding surfaces 260. The dies 260 can be positioned over the substrate bonding surface 258 such that the conductive features 272 of the die bonding layer 264 are aligned with conductive features 270 of the substrate bonding layer 256 while the non-conductive field regions of the die bonding surface 268 are aligned with non-conductive field regions of the substrate bonding surface 258. This arrangement results in the formation of a hybrid bond between the substrate 252 and the dies 260 that includes dielectric-to-dielectric direct bonds formed between the non-conductive field regions of the dies and the substrate and metal-to-metal direct bonds formed between the conductive features 270 of the substrate 252 and the conductive features 272 of the dies 260.

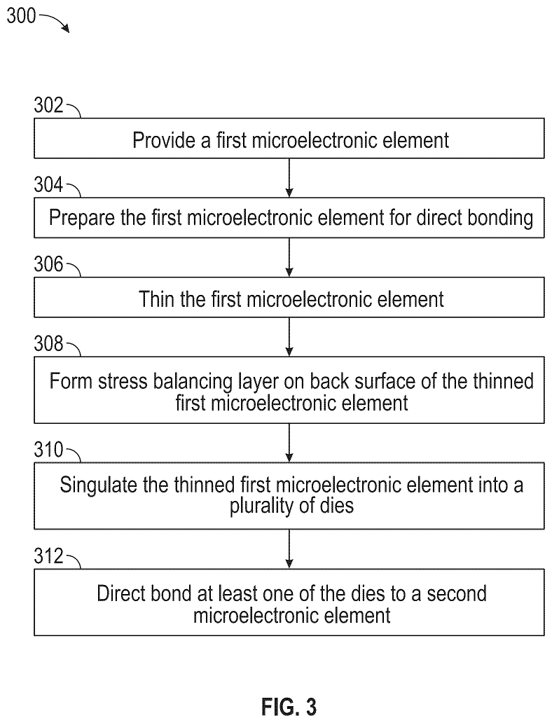

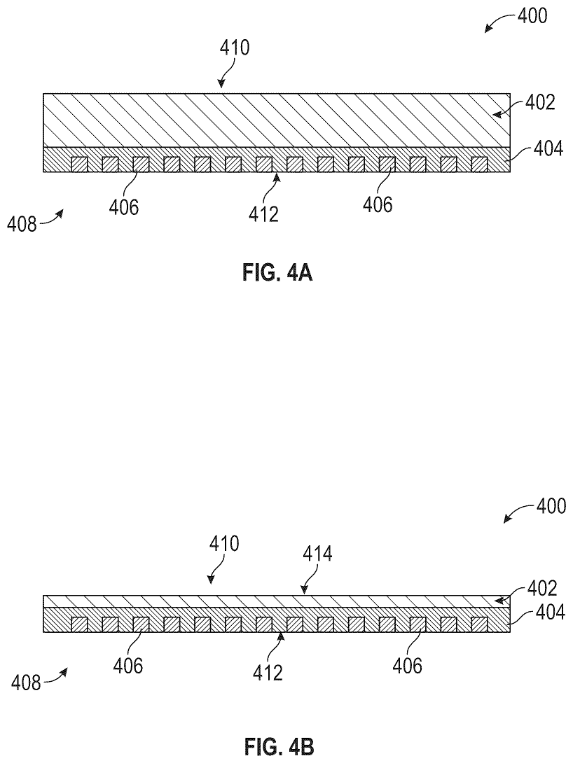

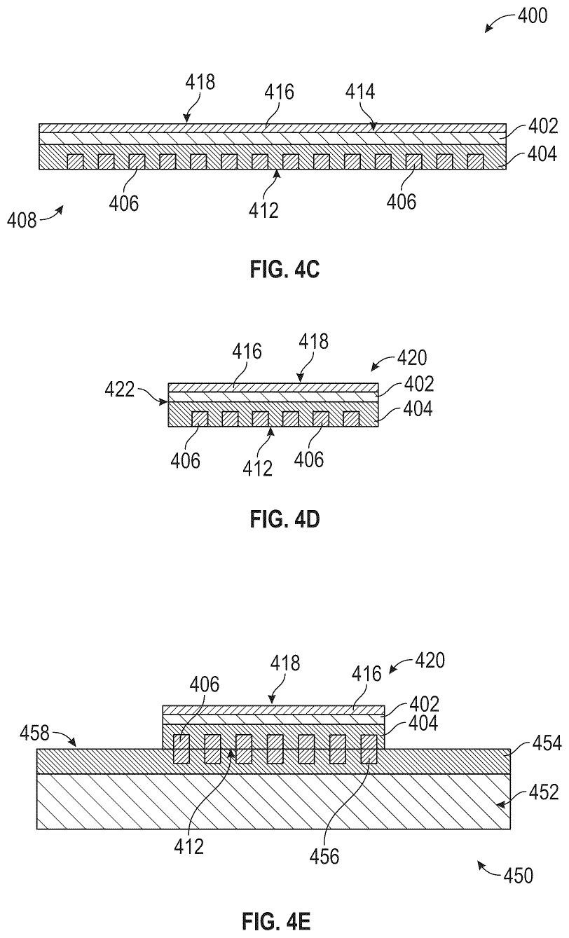

FIG. 3 is a flowchart illustrating a D2W process 300 for reducing die warpage and ensuring good quality direct bonding between two microelectronic (e.g., semiconductor) elements. While described in terms of a D2W embodiment, the skilled artisan will appreciate that the principles and advantages taught herein are also applicable to D2D bonding. FIGS. 4A-4G are schematic side sectional views of microelectronic elements at various blocks of the D2W process 300 shown in FIG. 3.

As shown in FIG. 4A, at block 302, a microelectronic element 400 is provided. The microelectronic element 400 includes a base portion 402 and a bonding layer 404. The bonding layer 404 includes conductive elements 406 and a non-conductive material in which the conductive elements 406 are at least partially embedded. The microelectronic element 400 includes a front side 408 and a back side 410, where the front and back sides 408, 410 are on opposing sides of the microelectronic element 400 and the front side 408 includes a bonding surface 412 formed by the bonding layer 404. The bonding surface 412 includes the exposed portions of the conductive elements 406 and the non-conductive material in which the conductive elements 406 are at least partially embedded. As discussed above in connection with FIG. 1A, in some embodiments, the conductive elements 406 can be recessed below the surface of the bonding layer 404. For semiconductor element embodiments, the microelectronic element 400 of FIG. 4A can be a wafer or a reconstituted wafer prior to thinning.

As described above in connection with FIGS. 1A and 1B, in some embodiments, the base portion 402 can comprise a device portion, such as a bulk semiconductor (e.g., silicon) portion of the microelectronic element 400 and BEOL interconnect layers over such semiconductor portions. Active devices and/or circuitry can be patterned and/or otherwise disposed in or on the base portion 402. Active devices and/or circuitry can be disposed at or near the front side 408 of the base portion. In other embodiments, the base portion 402 may not include active circuitry, but may instead comprise dummy substrates, interposers, passive optical elements (e.g., glass substrates, gratings, lenses), etc. As noted with respect to the embodiment of FIG. 2A, where the microelectronic element 400 is a semiconductor element, BEOL layer(s) (not shown) can be considered part of the bonding layer 404, part of the base portion 402, or positioned between the bonding layer 404 and the base portion 402.

At block 304, the microelectronic element 400 can be prepared for bonding. As described above in connection with FIGS. 1A and 1B, preparing the microelectronic element 400 for bonding can include polishing the bonding surface 412 of the bonding layer 404, activating the bonding surface 412, and/or terminating the bonding surface 412 with suitable species.

As shown in FIG. 4B, at block 306, the microelectronic element 400 is thinned. The element 400 can be thinned by removing material from the back side 410 of the base portion 402 of the microelectronic element 400. The thinned base portion 402 of the microelectronic element 400 includes a back surface 414, where the back surface 414 and the bonding surface 412 are on opposing sides of the microelectronic element 400. In some embodiments, thinning the microelectronic element 400 by removing material from the back side 410 can be done by grinding away the back side 410 of bulk semiconductor material, such as silicon. In some embodiments, the microelectronic element 400 can be thinned using other techniques in addition to or instead of grinding. For example, in some embodiments, thinning the microelectronic element 400 can include etching and/or CMP of the back side 410. In some embodiments, the microelectronic element 400, such as a standard 300-mm wafer, can have an initial thickness of about 750 μm and can be thinned to have a thickness of about 100 μm. In other embodiments, however, the microelectronic element 400 can have a different initial thickness and can be thinned to have a different thickness. For example, in some embodiments, the microelectronic element 400 can have an initial thickness of about 800 μm, about 790 μm, about 780 μm, about 770 μm, about 760 μm, about 750 μm, about 740 μm, about 730 μm, about 720 μm, about 710 μm, about 700 μm, or a value in a range defined by any of these values and can be thinned to have a thickness of about 2 μm, about 5 μm, about 10 μm, about 20 μm, about 30 μm, about 50 μm, about 100 μm, about 150 μm, about 180 μm, about 200 μm, about 240 μm, about 300 μm, or a value in a range defined by any of these values. In some embodiments, the microelectronic element 400 can have an initial thickness between about between about 500 μm and about 950 μm, between about 600 μm and about 900 μm, between about 700 μm and about 800 μm, between about 700 μm and about 750 μm, between about 750 μm and about 800 μm, between about 720 μm and 770 μm, or a value in a range defined by any of these values and can be thinned to have thickness between about 2 μm and about 300 μm, between about 5 μm and about 100 μm, between about 10 μm and about 50 μm, between about 5 μm and about 30 μm, between about 30 μm and about 100 μm, between about 100 μm and about 300 μm, or a thickness in a range defined by any of these values.

As shown in FIG. 4C, at block 308, a stress balancing layer 416 is formed onto the back surface 414 of the base portion 402 of the thinned microelectronic element 400. After forming the stress balancing layer 416, the stress balancing layer defines a back surface 418 of the microelectronic element 400. As described above in connection with FIG. 2, the stress balancing layer 416 is formed from a dielectric material (e.g., the inorganic dielectric materials noted above) and is configured to balance stresses of the microelectronic element 400 so that a die formed from the microelectronic element 400 is bondable, taking into account the factors noted above with respect to Equation 1. Accordingly, forming the stress balancing layer 416 on the back surface 414 of the base portion 402 can include depositing a sufficient amount of dielectric material onto the back surface 414 of the base portion 402 so that the die formed microelectronic element 400 is bondable, accounting for warp, ridigity and stiffness. In some embodiments, the stress balancing layer 416 is formed by depositing the dielectric material without patterning it. In some embodiments, the stress balancing layer 416 can be formed such that it has a thickness between 0.5 μm and about 10 μm, between about 0.5 μm and about 1 μm, between about 0.5 μm and about 2 μm, between about 0.5 μm and about 3 μm, between about 0.5 μm and about 4 μm, between about 0.5 μm and about 5 μm, between about 1 μm and about 5 μm, between about 2 μm and about 5 μm, between about 5 μm and about 10 μm, or a thickness in a range defined by any of these range. As discussed in greater detail elsewhere in the application, in some embodiments, the thickness of the stress balancing layer 416 can be based at least in part on one or more of the thickness of the thinned microelectronic element 400, the dimensions of the die to be formed from the microelectronic element 400, the thickness and/or dimensions of the microelectronic element 400 prior to thinning, a measured bowing and/or warpage of the microelectronic element 400 (either pre-thinning or post-thinning), and a composition of the base portion 402, the bonding layer 404, any additional BEOL layers on the front side, and/or the dielectric that forms the stress balancing layer 416.

In some embodiments, the stress balancing layer 416 can be formed such that the thickness of the stress balancing layer 416 is uniform or constant for the entire microelectronic element 400. In other embodiments, however, the stress balancing layer 416 can be selectively patterned or etched so that the stress balancing effect of the stress balancing layer 416 can vary across the microelectronic element 400. For example, in some embodiments, the thickness of the stress balancing layer 416 at a given point on the microelectronic element 400 can depend on the distance from the edge of the microelectronic element 400 to the point. Additionally, in the illustrated embodiment, the stress balancing layer 416 is formed over the entire back surface 414 of the base portion 402. In other embodiments, however, some portions of the stress balancing layer 416 can be completely etched away or otherwise removed from some portions of the back surface 414.

As shown in FIG. 4D, at block 310, the microelectronic element 400 is singulated to form at least one die 420. The die 420 includes a portion of the base portion 402, the bonding layer 404, any additional BEOL layers formed at the wafer level, one or more of the conductive features 406, a portion of the bonding surface 412, a portion of the stress balancing layer 416, and a portion of the back surface 418. The microelectronic element 400 can be singulated using any suitable singulation process, such as saw singulation, laser singulation, plasma or ion beam singulation, etc. As a result of the singulation process, the die 420 can have side surfaces 422. The side surfaces 422 of the various layer of the die 420 are substantially flush and extend between the bonding surface 412 on a front side of the die 420 and the back surface 418 on a back side of the die. The intersections of the side surfaces 422 and the back surface 418 form edges of the back surface 418 that define a perimeter of the back surface 418. In some embodiments, the dielectric material that forms the stress balancing layer 416 does not extend beyond the perimeter of the back surface 418 and does not contact the side surfaces 422. In some embodiments, the microelectronic element 400 can be singulated such that the die 420 has a width of about 8 mm and a length of about 12 mm, a width of about 3 mm and a length of about 3 mm, a length of about 1 mm and a length of about 1 mm, or a width of 0.4 mm and a length of about 0.4 mm. In other embodiments, however, the microelectronic element 400 can be singulated such that the die 420 has different dimensions. For example, in some embodiments, the die 420 can have a width between about 0.1 mm and about 70 mm, between about 0.2 mm and about 50 mm, between about 0.4 and about 25 mm, between about 0.4 mm and about 10 mm, between about 0.4 mm and about 8 mm, between about 1 mm and about 8 mm, between about 1 mm and about 3 mm, between about 3 mm and 8 mm, or a value in a range defined by any of these ranges, and can have length between about 0.1 mm and about 70 mm, between about 0.2 mm and about 50 mm, between about 0.4 and about 25 mm, between about 0.4 mm and about 10 mm, between about 0.4 mm and about 8 mm, between about 1 mm and about 8 mm, between about 1 mm and about 3 mm, between about 3 mm and 8 mm, or a value in a range defined, or a value in a range defined by any of these ranges.

As shown in FIG. 4E, at block 312, the die 420 is direct bonded to a second microelectronic element 450. The second microelectronic element 450 includes a base portion 452 and a bonding layer 454, where the bonding layer 454 comprises a non-conductive material (e.g., a dielectric material) and a plurality of conductive features 456 at least partially embedded in the dielectric material. The non-conductive material and the conductive features 456 form a bonding surface 458. As noted above, the skilled artisan will appreciate that the second microelectronic element 450 can also include multiple BEOL layers at its front side. Such BEOL layers can be considered to lie between the bonding layer 458 and its base portion 452, or can be considered to be part of the bonding layer 454 or part of the base portion 452. In some embodiments, the second microelectronic element 450 comprises a wafer. In other embodiments, the second microelectronic element 450 comprises an integrated device die, an interposer, or other sacrificial carrier. In some embodiments, the bonding surface 458 can be prepared for direct bonding, such as by polishing it to a high degree of smoothness, activating it, and/or terminating it with a suitable species. In other embodiments, only one of the two bonding surfaces 458 is activated and/or terminated.

As described above in connection with FIGS. 1A and 1B, the die 420 is direct bonded to the microelectronic element 450 without an intervening adhesive. The die 420 can be direct bonded to the microelectronic element 450 by bringing the die bonding surface 412 into contact with the bonding surface 458 such that the non-conductive portions of the die bonding surface 412 are in direct contact with non-conductive portions of the bonding surface 458 and the conductive elements 416 are in direct contact with the conductive elements 456. Upon the bonding surfaces 412, 458 coming into contact with each other, direct non-conductive-to-non-conductive (e.g., dielectric-to-dielectric) covalent bonds can form, even at room temperature, when adequately prepared for direct bonding. In some embodiments, upon the bonding surfaces 412, 458 coming into contact with each other, one or more direct conductor-to-conductor (e.g., metallic-to-metallic) bonds can at least begin to form. In some embodiments, the bonded die 420 and microelectronic element 450 can be annealed to increase the strength of the conductor-to-conductor direct bond. In some embodiments, however, the conductive features on the bonding surfaces 412, 458 can be recessed below the bonding surface such that the conductive elements 416 are not in direct contact with the conductive elements 456 upon the bonding surfaces 412, 458 contacting each other at room temperature. In these embodiments, heating the bonded die 420 and the microelectronic element 450 during the annealing process can cause the conductive elements 416, 456 to expand across the gap between them, and merge with one another with the pressure of the expansion and increased metal atom mobility of the anneal to form the conductor-to-conductor metallic direct bond.

In the embodiments shown in FIGS. 3 and 4A-4E, the die 420 and the microelectronic element 450 both include conductive elements 406, 456 and are direct bonded together to form a hybrid bond that includes both non-conductive-to-non-conductive direct bonds and conductor-to-conductor direct bonds. In other embodiments, however, one or both of the die 420 and the microelectronic element 450 do not include conductive elements 406, 456. In these embodiments, the die 420 and the microelectronic element 400, 450 can be direct bonded together with blanket non-conductive-to-non-conductive direct bonds. The die backside stress balancing layer 416, as described herein, can advantageously facilitate either uniform direct bonding and hybrid bonding.

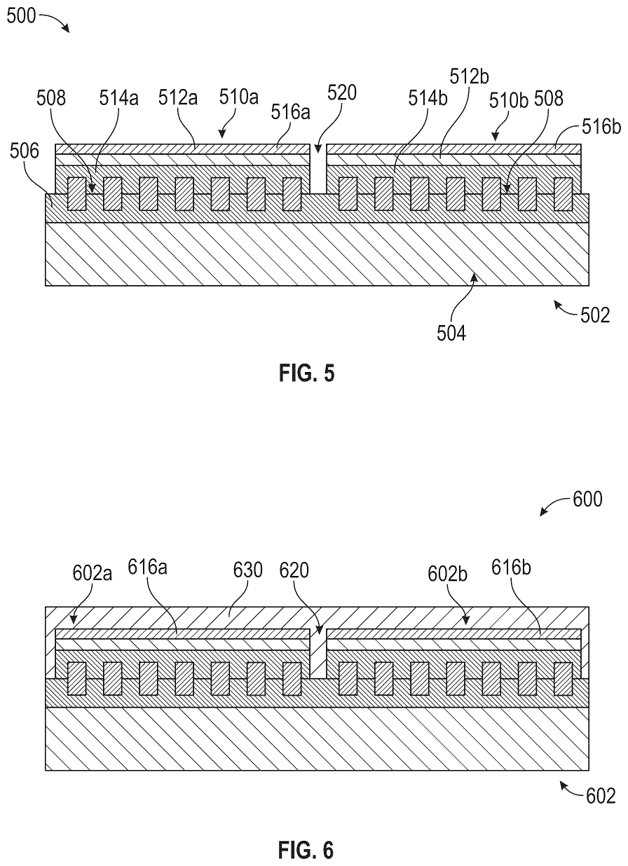

In the embodiments shown in FIGS. 4A-4E, a single die 420 is bonded to the microelectronic element 450. In other embodiments, however, multiple dies can be bonded to the substrate. For example, FIG. 5 illustrates a bonded structure 500 that includes multiple thinned dies directly bonded to a substrate. Unless otherwise noted, features of bonded structure 500 may be generally similar to features of bonded structure 200 of FIG. 2A and bonded structure 250 of FIG. 2B. The bonded structure 500 includes a substrate 502 and first and second dies 510a, 510b. The substrate 502 includes a substrate base portion 504 and a substrate bonding layer 506 that defines a substrate bonding surface 508. The first die 510a includes a first die base portion 512a, a first die bonding layer 514a, and a first stress balancing layer 516a. Similarly, the second die 510b includes a second die base portion 512b, a second die bonding layer 514b, and a second stress balancing layer 516b. As noted elsewhere herein, each of the elements can include multiple BEOL layers, either as part of the bonding layers or between their bonding layers and their respective base portions. The first and second dies 512a, 512b are each directly bonded to the substrate 502 and are separated from each other by a lateral gap 520. The lateral gap 520 can extend from the substrate bonding layer 506 to back surfaces 518a, 518b of the first and second dies 512a, 512b. In some embodiments, the stress balancing layers 516a, 516b do not extend into the lateral gap 520.

In some embodiments, after bonding the one or more dies to the substrate, one or more additional layers can be formed over the dies. For example, in some embodiments, a reconstitution layer can be deposited over the dies to form a reconstituted wafer. FIG. 6 illustrates a bonded structure 600 that includes a reconstitution layer formed over multiple dies bonded to a substrate. Unless otherwise noted, the bonded structure 600 may be generally similar to features of the bonded structure 200 of FIG. 2A, the bonded structure 250 of FIG. 2B, and/or the bonded structure 500 of FIG. 5. The bonded structure 600 includes a substrate 602, first and second dies 610a, 610b that are thinned and directly bonded to the substrate 602, and a reconstitution layer 630 formed over the thinned dies 610a, 610b and the substrate 602. The dies 610a, 610b can each include stress balancing layers 616a, 616b and can be separated from each other by a lateral gap 620. The reconstitution layer 630 can be formed over the stress balancing layers 616a, 616b and can at least partially fill the lateral gap 620. In some embodiments, the reconstitution layer 630 can be configured to isolate the dies 610a, 610b from each other. In some embodiments, the reconstitution layer can be configured to provide support to the bonded structure 600. In some embodiments, the reconstitution layer 630 can be formed from a dielectric material. For example, in some embodiments, the reconstitution layer 630 can be formed from one or more inorganic dielectric materials such as an oxide, nitride, which may include silicon dioxide, silicon nitride or other dielectric compound of silicon such as SiCOH. In other embodiments, the dielectric material can comprise an inorganic dielectric, including various polymers like epoxies, polyimide, thermoplastics, thermoset plastics, among others. Either organic or inorganic materials can be employed to serve as protective encapsulants, or can be planarized to serve as a reconstituted substrate (e.g., wafer) for further processing.

To ensure that the stress balancing layer sufficiently reduces the stress imbalances and the die is sufficiently flat, the thickness of the stress balancing layer should be carefully selected. If the stress balancing layer is not thick enough, the stress balancing layer will not sufficiently reduce the stress imbalance and the die will have poor bondability. Conversely, if the stress balancing layer is too thick, the stress balancing layer may actually cause bow in the opposite direction, and/or reduce bondability by increasing stiffness and/or rigidity, which may effectively call for even greater flatness to achieve bondability. Accordingly, the thickness of the stress balancing layer can account for the effect of rigidity and stiffness on bondability. This means that the stress balancing layer need not be engineered to perfectly balance stresses, saving the time and cost of such over-engineering.

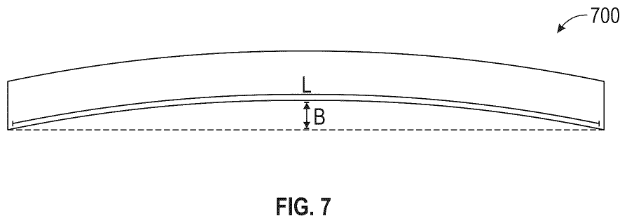

With reference to FIG. 7, in some embodiments, the selected for thickness of the stress balancing layer can be based in part on the amount that the die bows. However, it is not practical or cost effective to individually measure the bow of each die and selectively deposit the dielectric material based on the measured bow of each individual die. To that end, experiments and analysis have shown that the bow of the singulated die can be estimated using the bow of the substrate that was measured prior to the substrate being thinned and singulated. As is well known in the art, the Stoney equation relates the curvature of a substrate having a thin film formed on it to the stress in the film, and is shown as Equation 2:

$$σ = \frac{{h}^{2}}{6 {Rt}_{f}} \frac{E}{( 1 - v )} \qquad [ 2 ]$$

where σ is the stress in the film, h is the total thickness of the substrate, R is the radius of curvature of the substrate, tris the thickness of the thin film, E is the Young's modulus for the substrate, and ν is Poisson's ratio for the substrate. As is well known in the art, the radius of curvature R of the substrate can be calculated according to according to Equation 3:

$$R \approx - \frac{{L}^{2}}{8 B} \qquad [ 3 ]$$

where B is the measured bow of the substrate and L is the length of the horizontal path over which the bow is measured. The bow of an element is the deviation of the center point of the element from a reference plane over a given length. FIG. 7 illustrates a bowed microelectronic element 700 having a bow B and a length L over which the bow B is measured. The bow B is typically measured over a distance that depends on the width of the substrate such that the L can based on the size of the substrate. For example, in some embodiments, the length L can be 290 mm for a 300 mm wafer, 190 mm for a 200 mm wafer, 130 mm for a 150 mm wafer, or 85 mm for a 100 mm wafer, excluding the typical exclusion zones for such wafers. In other embodiments, however, the length L can be any suitable distance. The reference plane that the bow B is measured from is the plane connecting opposite ends of the element 700 and is represented by the dotted line.

The stresses in a thin film formed on a full-thickness wafer prior to thinning and in a thin film formed on the thinned die can be represented by Equations 4 and 5:

$${σ}_{1} = \frac{{h}_{1}^{2}}{6 \times {R}_{1} \times {t}_{f}} \times \frac{E}{( 1 - v )} \qquad [ 4 ]$$

$${σ}_{2} = \frac{{h}_{2}^{2}}{6 \times {R}_{2} \times {t}_{f}} \times \frac{E}{( 1 - v )} \qquad [ 5 ]$$

where σ₁ is the stress in a thin film formed on a full-thickness wafer prior to thinning and singulation, σ₂ is the stress in a thin film formed on the thinned die after singulation, h₁ is the total thickness of the unthinned wafer, h₂ is the total thickness of the thinned die, R₁ is the radius of curvature of the unthinned wafer, and R₂ is the radius of the thinned die. Similarly, the radius of curvature for the unthinned wafer and thinned die can be approximated by Equations 6 and 7:

$${R}_{1} \approx - \frac{{L}_{1}^{2}}{8 \times {B}_{1}} \qquad [ 6 ]$$

$${R}_{2} \approx - \frac{{L}_{2}^{2}}{8 \times {B}_{2}} \qquad [ 7 ]$$

where L₁ is the length over which the bow of the unthinned wafer is measured, B₁ is the bow of the unthinned wafer, L₂ is the length over which the bow of the thinned die is measured, and B₂ is the bow of the thinned die. Since the bow measurements are typically measured across the entire width of the element, in some embodiments, L₁ is approximately equal to the width of the wafer and L₂ is approximately equal to width of the die. Substituting Equation 6 into Equation 4 and substituting Equation 7 into Equation 5 results in Equations 8 and 9:

$${σ}_{1} = \frac{{h}_{1}^{2}}{6 \times {t}_{f}} \times [ \frac{8 \times {B}_{1}}{{L}_{1}^{2}} ] \times \frac{E}{( 1 - v )} \qquad [ 8 ]$$

$${σ}_{2} = \frac{{h}_{2}^{2}}{6 \times {t}_{f}} \times [ \frac{8 \times {B}_{2}}{{L}_{2}^{2}} ] \times \frac{E}{( 1 - v )} \qquad [ 9 ]$$

To determine the relationship between σ₁ (the stress in the thin film on the unthinned wafer) and σ₂ (the stress in the thin film on a die formed by thinning and singulating the wafer), testing was performed to measure the difference in stress in dielectric layer(s) formed on a substrate before and after thinning and singulating the substrate. The dielectric layer(s) can represent BEOL and any additional bonding layer on the front side of the die, causing the wafer and die bowing. The results of this testing indicated that the thinning and singulating processes that occur during the die formation process do not substantially change the stress in the thin film layer(s). This means that it can be assumed that σ₁ and σ₂ are approximately equal to each other. Using this assumption, Equations 8 and 9 can be set equal to each other, as shown in Equation 10:

$$\frac{{h}_{1}^{2}}{6 \times {t}_{f}} \times [ \frac{8 \times {B}_{1}}{{L}_{1}^{2}} ] \times \frac{E}{( 1 - v )} = \frac{{h}_{2}^{2}}{6 \times {t}_{f}} \times [ \frac{8 \times {B}_{2}}{{L}_{2}^{2}} ] \times \frac{E}{( 1 - v )} \qquad [ 10 ]$$

The Young's modulus E and the Poisson's ratio ν for the substrate are both material properties of the substrate material and are therefore unaffected by the thinning. Additionally, the thickness of the film t_{f} is also unaffected by the thinning process. Accordingly, Equation 10 can be simplified as shown in Equations 11 and 12:

$$\frac{{h}_{1}^{2} \times {B}_{1}}{{L}_{1}^{2}} = \frac{{h}_{2}^{2} \times {B}_{2}}{{L}_{2}^{2}} \qquad [ 11 ]$$

$${B}_{2} = {[ \frac{{h}_{1}}{{h}_{2}} ]}^{2} \times {[ \frac{{L}_{2}}{{L}_{1}} ]}^{2} \times {B}_{1} \qquad [ 12 ]$$

Equation 12 relates the bow measured for the unthinned wafer to the expected bow of the thinned die using the size and thickness of the unthinned wafer and the size and thickness of the thinned die.

This relationship between measured bow of the unthinned wafer and the bow of the thinned die can be used during a die bonding (e.g., D2W) process to more accurately determine how thick the stress balancing layer should be ensure that the stress balancing layer sufficiently reduces the stress imbalances and the die is sufficiently flat so that the die has good bondability.

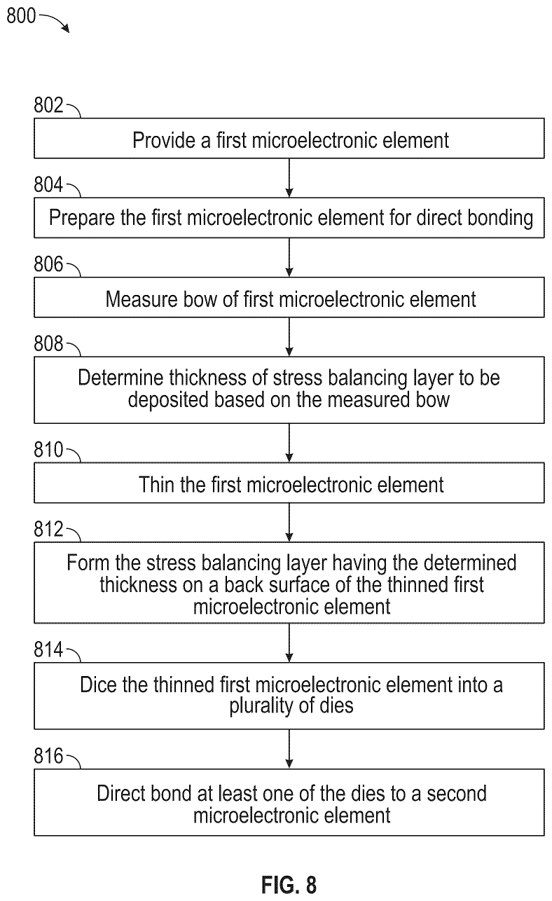

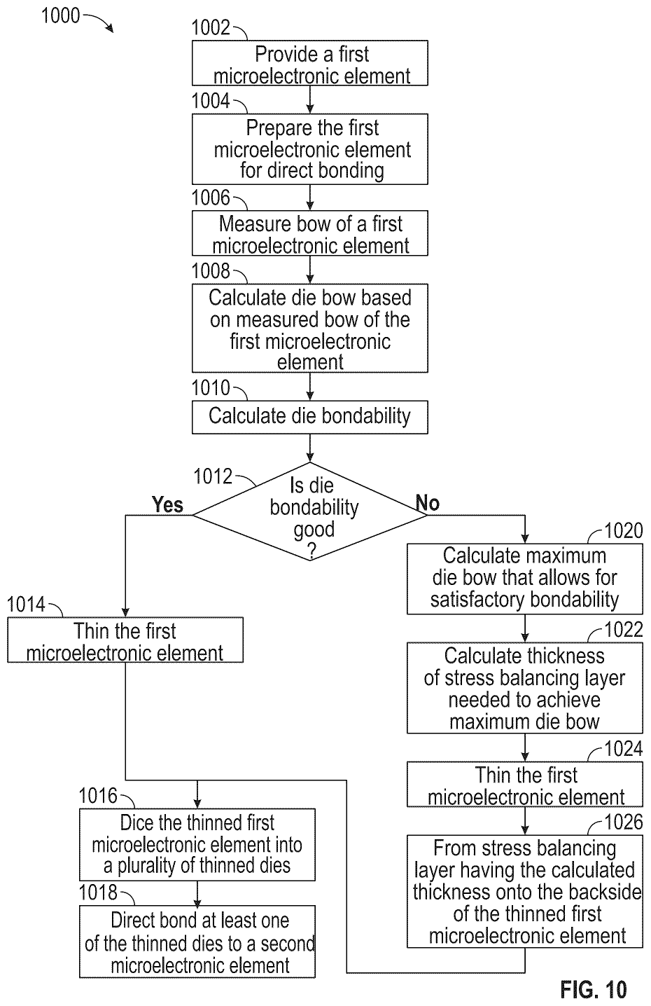

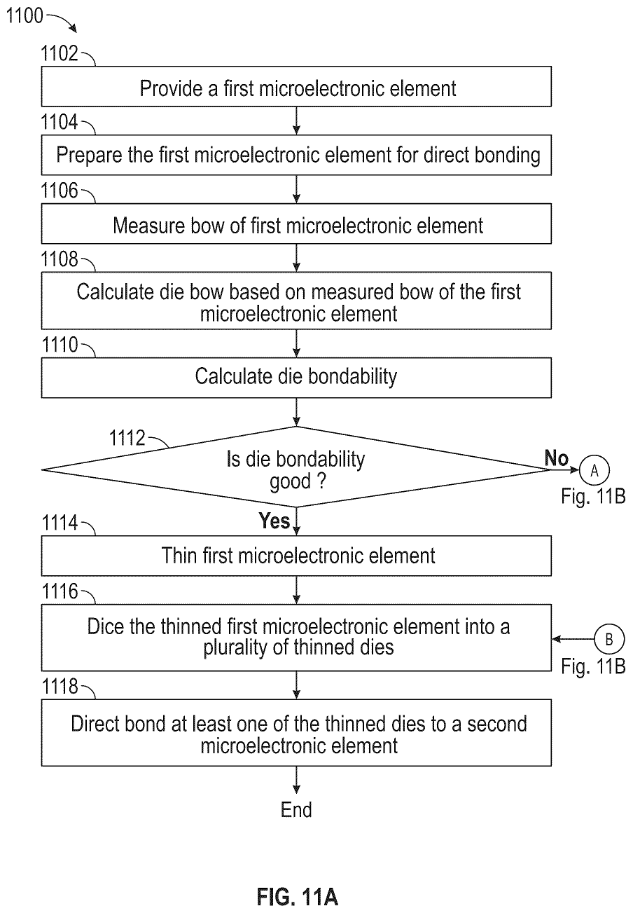

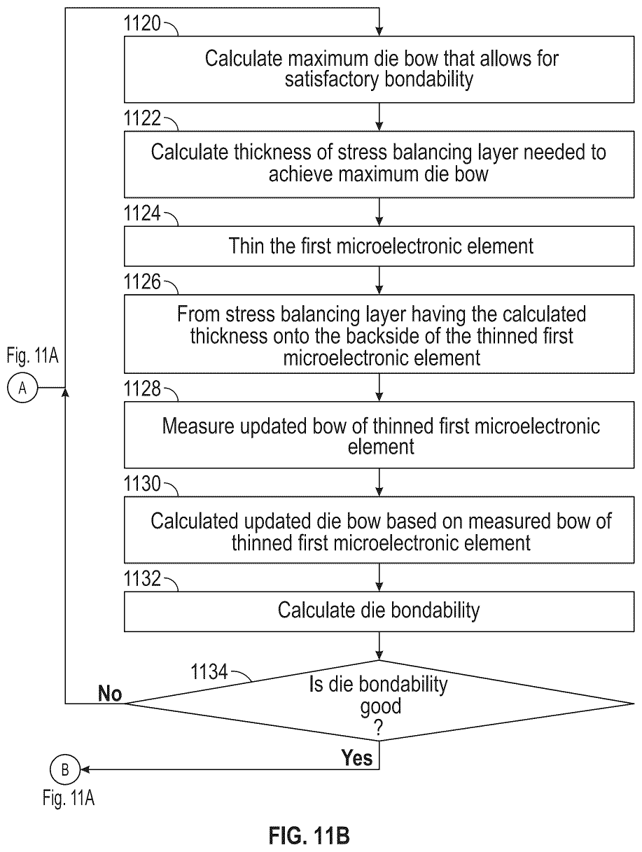

FIG. 8 is a flowchart illustrating a die bonding (e.g., D2W) process 800 for reducing die warpage and ensuring good quality direct bonding between microelectronic elements that includes forming a stress balancing layer having a thickness based, at least in part, on a measured bow of the wafer and expected bow of the die, as discussed above. Unless otherwise noted, the individual blocks of D2W process 800 may be generally similar to the individual blocks of die bonding process 300 shown and described above in connection with FIG. 3. In some embodiments, selection of the stress balancing layer can also be based in part on other factors beyond just expected die bow, such as the rigidity and stiffness factors embodied in Equation 1, as discussed in more detail below with respect to FIGS. 10 and 11.

At block 802, a first microelectronic element is provided. The first microelectronic element can have features and properties that are generally similar to the microelectronic element 400 shown in FIG. 4A.

At block 804, the first microelectronic element can be prepared for direct bonding. As described above in connection with FIGS. 1A and 1B and block 304 of FIG. 3, preparing the microelectronic element for bonding can including polishing the bonding surface of the bonding layer, activating the bonding surface, and/or terminating the bonding surface with a suitable species.

At block 806, the bow of the first microelectronic element is measured. In some embodiments, the bow of the first microelectronic element can be measured.

At block 808, a thickness of the stress balancing layer to be formed is determined based at least in part on the measured bow. As discussed in greater detail elsewhere in the specification, the stress balancing layer on the back of a die is configured to at least partially counter expected (post-thinning and post-singulation) die bow and cause the die to remain sufficiently flat for bonding. Additionally, as previously discussed, Equation 12 allows for the expected (post-thinning and post-singulation) die bow to be estimated based at least in part on the measured bow of the (pre-thinning and pre-singulation) microelectronic element (e.g., wafer), along with the thickness of the unthinned microelectronic element, the thickness of the die, the width of the unthinned microelectronic element, and the width of the die. The width and thickness of the unthinned microelectronic element is known, and the width and thickness of the die can be pre-selected. Accordingly, in some embodiments, the thickness of the stress balancing layer for countering expected bow in the thinned and singulated die can be based at least in part on the measured bow of the unthinned microelectronic element.

At block 810, the first microelectronic element is thinned. As described above in connection with block 306 of FIG. 3, the first microelectronic element can be thinned by removing material from the back side of the base portion (e.g., bulk semiconductor material) of the microelectronic element. In some embodiments, thinning the microelectronic element by removing material from the back side can be done by grinding away the back side. In some embodiments, the microelectronic element can be thinned using other techniques in addition to or instead of grinding. For example, in some embodiments, thinning the microelectronic element can include etching and/or CMP of the back side. In some embodiments, after thinning the microelectronic element, the thinned microelectronic element can have a back surface. In some embodiments, the microelectronic element can be a standard silicon wafer with an initial bulk semiconductor thickness of about 775 μm and can be thinned to have a total thickness (including front side devices and BEOL stack) of 100 μm or less. In other embodiments, however, the microelectronic element can have a different initial thickness and can be thinned to have a different thickness. For example, in some embodiments, the microelectronic element can have an initial thickness between about 300 μm and about 950 μm, between about 300 μm and about 600 μm, between about 600 μm and about 900 μm, between about 500 μm and about 700 μm, between about 700 and about 800 μm, between about 700 μm and about 750 μm, between about 750 μm and about 800 μm, between about 720 μm and 770 μm, or a value in a range defined by any of these values. Thus, the methods described herein can be applied to any of a number of standard substrates, such as but not limited to four-inch wafers (450 μm thick), six-inch wafers (650 μm thick), 200-mm wafers (725 μm thick), 300-mm wafers (775 μm thick), and 450-mm wafers (950 μm thick). The microelectronic element can be thinned to have thickness between about 2 μm and about 600 μm, between about 2 μm and about 100 μm, between about 2 μm and about 50 μm, between about 5 μm and about 30 μm, between about 30 μm and about 100 μm, between about 100 μm and about 300 μm, between about 300 μm and about 600 μm, or a thickness in a range defined by any of these values.

The skilled artisan will appreciate that the sequence among some of the blocks in FIG. 8, such as between blocks 808 and 810, can be conducted in sequences other than those illustrated.

At block 812, the stress balancing layer having the determined thickness is formed on the back surface of the thinned first microelectronic element. The stress balancing layer can be formed by depositing a dielectric material (e.g., one of the inorganic dielectric materials noted above) over the back surface of the thinned first microelectronic element. For example, in some embodiments, the stress balancing layer can be formed on the back surface using a vapor deposition process, such as PVD or CVD, or by a spin-on deposition process, to deposit the dielectric material onto the substrate. In some embodiments, forming the stress balancing layer can include depositing the dielectric material onto the back surface until the layer of dielectric material has the determined thickness. In other embodiments, the stress balancing layer can be formed by depositing the dielectric material onto the back surface of the thinned first microelectronic element until the layer of dielectric material is thicker than the predetermined thickness, and then the extra dielectric material can be removed (e.g., by grinding and/or etching the excess dielectric material). In some embodiments, the stress balancing layer is a blanket, unpatterned layer. In some embodiments, some portions of the stress balancing layer can be selectively etched away or patterned while other portions of the stress balancing layer are not etched (or are etched a different amount).

At block 814, after forming the stress balancing layer on the back surface of the thinned first microelectronic element, the thinned first microelectronic element is singulated into a plurality of dies. The thinned first microelectronic element can be singulated using any suitable singulation and/or dicing method. Each of the singulated dies can include a portion of the stress balancing layer formed in block 812 and a portion of the bonding surface, where the portion of the stress balancing layer forms a back side of the die. As described above in connection with FIG. 4, the singulated dies have side surfaces that are substantially flush such that the stress balancing layer does not extend beyond a perimeter of the back side of the dies. In some embodiments, the stress balancing layer for each of the dies can have the same thickness. In other embodiments, at least some of the dies can have a stress balancing layer having a different thickness.

At block 816, at least one of the singulated dies is direct bonded to a second microelectronic element without an intervening adhesive. In some embodiments, the second microelectronic element comprises a substrate, a wafer, or a die. The second microelectronic element includes a bonding surface. In some embodiments, the bonding surface of the second microelectronic element comprises a non-conductive material (e.g., a dielectric material). In some embodiments, the bonding surface of the second microelectronic element includes one or more conductive features corresponding to conductive features on the front side of the singulated die, and direct bonding comprises hybrid bonding.

As described in greater detail elsewhere in the specification, the at least one singulated die can be direct bonded to the second microelectronic element without an intervening adhesive by bringing the bonding surface of the singulated die into contact with the bonding surface of the second microelectronic element such that the non-conductive portions of the die bonding surface are in direct contact with non-conductive portions of second microelectronic elements. In embodiments where both the die bonding surface and the bonding surface of the second microelectronic element include conductive elements, the die can be directed to the second microelectronic element by bringing the bonding surface of the singulated die into contact with the bonding surface of the second microelectronic element such that the conductive elements of the die bonding surface are directly adjacent to the conductive elements of the second microelectronic element. Upon the bonding surfaces contacting each other, direct non-conductive-to-non-conductive (e.g., dielectric-to-dielectric) covalent bonds can form. In some embodiments, upon the bonding surfaces coming into contact with each other, one or more direct conductor-to-conductor (e.g., metallic-to-metallic) bonds can form. In some embodiments, the bonded die and microelectronic element can be annealed to increase the strength of the bonds. In some embodiments, however, the conductive features on the bonding surfaces can be recessed below the bonding surface such that the conductive elements are not in direct contact with the conductive elements when the non-conductive bonding surfaces initially contact each other. In these embodiments, heating the bonded die and the microelectronic element during the annealing process can cause the conductive elements to expand into each other to form the conductor-to-conductor metallic direct bond to complete the hybrid bond.

In the embodiment shown in FIG. 8, the wafer bow is measured before the wafer is thinned and this measured bow is used to determine the thickness of the stress balancing layer to be deposited. However, the skilled artisan will appreciate that the sequences can be changed from the order shown in FIG. 8, absent specific indication otherwise.

As previously discussed, the bondability of a die used in direct bonding processes can relate not only to warpage or bow, but also to rigidity, and stiffness of the die and this relationship can be represented by Equation 1 above. To determine the value of the constant coefficients C₁, C₂, C₃, and C₄, the bondability of different dies having different sizes, thicknesses, number and type of metallization layers, dielectric layer(s), and die bow was tested. Each of the dies was direct bonded to another microelectronic element (e.g., to a substrate) and the resulting direct bonds were then analyzed for their quality. For each bonded die, a bondability score was assigned, where a bondability score of 1 corresponded to a normal or good direct bond, a bondability score of 0.5 corresponded to a marginal direct bond, a bondability score of 0.25 corresponded to a marginal to poor direct bond, and a bondability score of 0 corresponded to no bond forming. A multivariate regression analysis was then performed to determine the effect that the warpage, rigidity, and stiffness had on the die bondability. The multivariate regression analysis indicated that the values of the constant coefficients C₁, C₂, C₃, and C₄ were different for each die size but that, in general, the die warpage is the most significant factor to the die's bondability. However, the analysis also showed that the significance of the rigidity and stiffness on the bondability of the die increased with increasing die size. This is likely because larger dies are more flexible than smaller dies, meaning that larger dies can flex more during the direct bonding process and are therefore more able to offset and/or accommodate more die warpage than smaller dies, and can therefore remain sufficiently flat during direct bonding to facilitate the formation of a good direct bond. On the other hand, accounting only for warpage by attempting to zero expected die bow with a relatively thick backside dielectric can have adverse effects on bondability. Without wishing to be limited to theory, such adverse effects may be due to the fact that focusing solely on addressing warpage can lead to a stress balancing layer that excessively increases rigidity and stiffness, leaving the die with insufficient flexibility to overcome local variations in planarity and other imperfections in the die bonding surface.

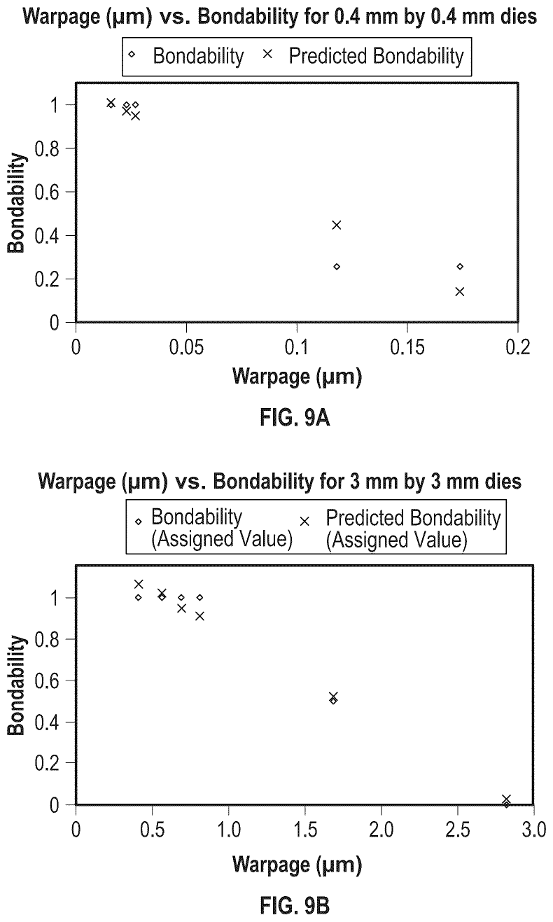

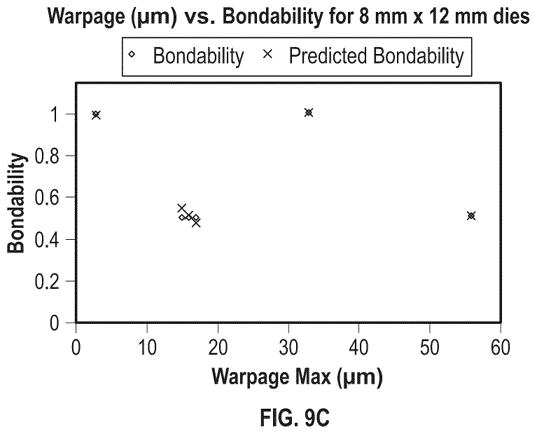

FIGS. 9A-9C are graphs showing the relationship between die warpage and die bondability for dies of different sizes. The graph in FIG. 9A shows the relationship between die warpage and die bondability for dies having a die size of 0.4 mm by 0.4 mm. For dies of this size, the bondability of the die is effectively dependent on the warpage of the die, as shown by the near-linear relationship between warpage and bondability. Accordingly, the coefficient C₁ for dies of this size was significantly larger than coefficients C₂ and C₃, and the p-value of the die warpage was about 0.01. The graph in FIG. 9B shows the relationship between die warpage and die bondability for dies having a die size of 3 mm by 3 mm. For die this size, the bondability of the die is still predominantly linearly dependent on the die warpage (p-value of 0.004), but the rigidity and stiffness also have an effect (p-values of 0.734 and 0.693, respectively). The graph in FIG. 9C shows the relationship between die warpage and die bondability for dies having a die size of 8 mm by 12 mm. For dies of this size, while the die bondability is generally still dependent on the warpage (p-value of 0.003), the rigidity and stiffness (p-values 0.09 and 0.465, respectively) have significantly greater impacts on the die bondability. This suggests that some larger dies having relatively high warpage can still have good bondability while other larger dies having relatively less warpage can have poor bondability if the die is too rigid and/or stiff. This is reflected in FIG. 9C which shows that the bondability of a die having a warpage of about 33 μm can have a similar bondability as a die having a warpage of about 3 μm and significantly better bondability than dies having a warpage between about 15 μm and about 17 μm.

FIGS. 9A-9C also show the predicted bondability for each die using Equation 1, where the values of the constant coefficients C₁, C₂, C₃, and C₄ were calculated using the multivariate regression approach described above. Accordingly, by comparing the measured bondability scores to the predicted bondability scores, FIGS. 9A-9C also indicate the accuracy and effectiveness of using the multivariate regression approach in combination with Equation 1 to predict the bondability of the dies. FIG. 9A shows that the predicated bondability values for each of the 0.4 mm by 0.4 mm dies are close to the actual bondability of the same dies and a statistical evaluation of the model resulted in an adjusted R² value of about 0.9, suggesting that the predictive model can be used to successfully predict the bondability of 0.4 mm by 0.4 mm dies. Similarly, FIG. 9B shows that the predicted bondability values for each of the 3 mm by 3 mm dies is close to the actual bondability of these same dies. A statistical evaluation of this model resulted in an adjusted R² value of 0.975, which means that the predictive model for the bondability of the 3 mm by 3 mm dies is even more accurate than model for the 0.4 mm by 0.4 mm dies. Finally, FIG. 9C also shows that the predicted bondability values for each of the 8 mm by 12 mm dies is very close to the actual bondability of these same dies and the adjusted R² value for this model is 0.987, indicating that it is even more accurate for these larger dies.

In the embodiments shown and described in connection with FIGS. 9A-9C, the bondability of a die is given a score between 0 and 1. However, this is only one way of representing bondability and, in other embodiments, other ways of representing bondability can be used. For example, in some embodiments, the bondability value can be a percentage value that represents the likelihood that a die having the given warpage, rigidity, and stiffness will successfully form a good quality direct bond. The assigned bondability score can represent, for example, relative area of the surfaces bonded without void formation, or by reliability of conductive contacts formed in hybrid bonding. In general, any suitable way of representing the bondability of a die can be used.

The die bow model and the bondability prediction model can be used together to determine the thickness of the stress balancing layer needed to offset the stress imbalances in the die so that the die has good bondability. FIG. 10 is a flowchart illustrating a die bonding (e.g., D2W) process 1000 that includes calculating a die bondability and forming a stress balancing layer having a thickness sufficient to ensure that the die has good bondability. Unless otherwise noted, the individual blocks of die bonding process 1000 may be generally similar to the individual blocks of die bonding processes 100, 300, and 800 shown and described above in connection with FIGS. 1, 3, and 8, respectively.

At block 1002, a first microelectronic element is provided. The first microelectronic element can have features and properties that are generally similar to the microelectronic element 400 shown in FIG. 4A.

At block 1004, the first microelectronic element can be prepared for direct bonding. As described above in connection with FIGS. 1A and 1B and block 304 of FIG. 3, preparing the microelectronic element for bonding can including polishing the bonding surface of the bonding layer, activating the bonding surface, and/or terminating the bonding surface with a suitable species.

At block 1006, the bow of the first microelectronic element is measured.

At block 1008, a die bow can be calculated based on the measured bow of the first microelectronic element. As described above in connection with FIG. 8 and block 808, Equation 12 can be used to estimate the bow of a thinned and singulated die based at least in part on the measured bow of the unthinned and pre-singulation first microelectronic element (e.g., wafer), along with the thickness of the unthinned first microelectronic element, the thickness of the die, the width of the unthinned first microelectronic element, and the width of the die.

At block 1010, a die bondability is calculated. In some embodiments, the die bondability is calculated using the previously described multivariate regression model. In some embodiments, the multivariate regression model can calculate a predicted bondability based at least in part on the calculated die bow (or warpage), the die size, the rigidity of the die, and the stiffness of the die.

At block 1012, whether the calculated die bondability is sufficiently good is determined. In some embodiments, determining whether the calculated die bondability is sufficiently good includes determining whether the calculated die bondability is above a threshold die bondability.

If the calculated die bondability is sufficiently good, the D2W process 1000 proceeds to block 1014. At block 1014, the first microelectronic element is thinned. In some embodiments, the first microelectronic element can be thinned until it has a predetermined thickness. In some embodiments, the predetermined thickness can be 250 μm or less, 200 μm or less, 150 μm or less, 100 μm or less, 50 μm or less, 20 μm or less, or a value in a range defined by any of these values. As described above in connection with block 306 of FIG. 3 and block 810 of FIG. 8, the first microelectronic element can be thinned by removing material from the back side of the base portion (e.g., bulk semiconductor material) of the microelectronic element grinding away the back side, by etching and/or by CMP of the back side. After thinning the first microelectronic element, at block 1016, the thinned microelectronic element can then be singulated into a plurality of thinned dies and then, at block 1018, at least one of the plurality of thinned dies can be direct bonded to a second microelectronic element. Block 1014 represents the possibility that for some predicted die bow, no stress balancing layer may be needed to achieve acceptable bondability.

On the other hand, if the calculated die bondability is not sufficiently good, the D2W process 1000 proceeds to block 1020. At block 1020, the maximum die bow that still allows for satisfactory bondability is calculated. Rather than simply minimizing die bow, the die bonding process 1000 of FIG. 10 can only partially correct expected die bow with a stress balancing layer while still obtaining sufficient bondability. In some embodiments, the die bondability model is used to calculate the maximum die bow that still allows for satisfactory bondability. For example, in some embodiments, the die bondability model is used to calculate the maximum die bow that still allows for satisfactory bondability by selecting a minimum satisfactory bondability (e.g., the threshold die bondability from block 1012), and then using Equation 1 to calculate a warpage by substituting the selected minimum satisfactory bondability for the bondability value in Equation 1, and then solving for the warpage, which is generally equivalent to the die bow. Accordingly, the calculation of the die bonding process 1000 accounts not only for die warpage or bow, but also for rigidity and stiffness, which in term depend in part on die dimensions. In other embodiments, however, the maximum die bow that still allows for satisfactory bondability is calculated using a different method.

At block 1022, the thickness the stress balancing layer to achieve the maximum die bow is calculated. In some embodiments, calculating the thickness of the stress balancing layer to achieve the maximum die bow includes calculating a difference between the maximum die bow that allows for satisfactory bondability and the estimated die bow calculated in block 1008. This calculated difference represents the amount of die bow that the stress balancing layer will correct for to ensure that the stresses are sufficiently balanced and the die has good bondability. In some embodiments, after calculating the amount of die bow that the stress balancing layer will correct for, the thickness of the stress balancing layer can be calculated. In some embodiments, there can be a linear relationship between the thickness of the stress balancing layer and the amount of die bow offset by the stress balancing layer, and this relationship can be initially determined experimentally, and subsequently the derived relationship can be employed to avoid or minimize experimentation in practice. In some embodiments, the relationship between the thickness of the stress balancing layer and the amount of die bow offset by the stress balancing layer can be dependent on the thickness of the die. For example, in some embodiments, the amount of die bow corrected for by a stress balancing layer having a given thickness can decrease as the thickness of the die increases. In some embodiments, the relationship between the thickness of the stress balancing layer can depend on the amount of die bow, the composition of the die, and/or the die size. Various other factors can also affect the relationship between the thickness of the stress balancing layer and the amount of die bow offset by the stress balancing layer. In some embodiments, the thickness of the stress balancing layer to offset the die bow and ensure that the die has good bondability can be estimated on a using Equations 13 and 14 below. Specifically, Equation 13 can be used to calculate the radius of curvature of the wafer after thinning the wafer:

$$\frac{1}{{R}_{2}} = \frac{1}{{R}_{1}} + ( \frac{1}{{h}_{2}^{2}} - \frac{1}{{h}_{1}^{2}} ) \times 6 \times {σ}_{1} \times {t}_{1} \times \frac{1 - v}{E} \qquad [ 13 ]$$

where R₁ is the radius of curvature for the wafer having an initial thickness h₁, R₂ is the estimated wafer radius after thinning the wafer from the initial thickness h₁ to a final thickness h₂, σ₁ is the stress in a thin film formed from the material of the stress balancing layer, t₁ is the thickness of the thin film, E is the Young's modulus for the substrate, and ν is Poisson's ratio for the substrate. After calculating the estimated radius of curvature R₂, Equation 14 can be used to estimate the thickness t_{f} of the stress balancing layer to offset the wafer bow:

$${t}_{f} = ( \frac{1}{{R}_{2}} - \frac{1}{{R}_{f}} ) \times \frac{{h}_{2}^{2}}{6 \times {σ}_{f}} \times \frac{E}{1 - v} \qquad [ 14 ]$$

where R_{f} is the desired radius of curvature of the wafer after thinning the wafer and depositing the stress balancing layer on the wafer, and of is the stress in a thin film formed from the material of the stress balancing layer. In general, a higher radius of curvature corresponds to a flatter wafer. Accordingly, the absolute value of the desired final radius of curvature R_{f} should be higher than R₂. For example, in embodiments where the wafer is intended to be perfectly flat, the final radius of curvature R_{f} is equal to infinity and Equation 14 can be simplified as shown in Equation 15:

$${t}_{f} = ( \frac{1}{{R}_{2}} ) \times \frac{{h}_{2}^{2}}{6 \times {σ}_{f}} \times \frac{E}{1 - v} \qquad [ 15 ]$$

Although Equations 13-15 relate to the radius of curvature and thickness of a wafer, experimental analysis has shown that the predicted wafer bow also accurately predicted the die bow after singulating the wafer. Accordingly, the film thickness t_{f} calculated in Equations 14 and 15 can be used as the desired thickness of the stress balancing layer for offsetting the expected die bow. However, using Equations 13-15 is only one possible method of calculating the thickness of the stress balancing layer. In other embodiments, the thickness of the stress balancing layer needed to (partially) offset the expected die bow and ensure that the die has good bondability can be determined using a different equation or process, such as using other equations and/or using maps showing anticipated thickness distribution across the wafer.

At block 1024, the first microelectronic element is thinned. In some embodiments, the first microelectronic element can be thinned until it has a predetermined thickness. In some embodiments, the predetermined thickness can be 250 μm or less, 200 μm or less, 150 μm or less, 100 μm or less, 50 μm or less, 20 μm or less, or a value in a range defined by any of these values. As described above in connection with block 306 of FIG. 3 and block 810 of FIG. 8, the first microelectronic element can be thinned by removing material from the back side of the base portion of the microelectronic element grinding away the back side, by etching and/or by CMP of the back side.

At block 1026, after thinning the first microelectronic element, a stress balancing layer having the thickness calculated in block 1022 is formed on the backside of the thinned first microelectronic element. The stress balancing layer can be formed by depositing a dielectric material over the back surface of the thinned first microelectronic element. In some embodiments, forming the stress balancing layer having the calculated thickness includes calculating an amount of dielectric material needed to form the stress balancing layer having the calculated thickness, and then depositing the calculated amount of dielectric material onto the backside of the thinned first microelectronic. In other embodiments, the stress balancing layer can be formed by depositing the dielectric material onto the back surface of the thinned first microelectronic element until the layer of dielectric material is thicker than the calculated thickness, and then the excess dielectric material can be removed (e.g., by grinding and/or etching the excess dielectric material). As noted above, the stress balancing layer of the die bonding process 1000 of FIG. 10 may only partially correct expected die bow, such that the stress balancing layer can be significantly thinner than the sum of an BEOL stack and bonding layer(s) on the front side of the die.

After forming the stress balancing layer on the backside of the thinned first microelectronic element, the process can proceed to block 1016. At block 1016, the thinned microelectronic element can then be singulated into a plurality of thinned dies and then, at block 1018, at least one of the plurality of thinned dies can be direct bonded to a second microelectronic element.

In the die bonding process 1000 shown in FIG. 10, the die bow model and the bondability prediction model are only used once throughout the process 1000. In other embodiments, however, the models can be used multiple times to ensure that the die has satisfactory bondability.

FIGS. 11A and 11B are a flow chart illustrating an a die bonding process 1100 that can include iteratively calculating die bow and die bondability multiple times. Unless otherwise noted, the individual blocks of die bonding process 1100 may be generally similar to the individual blocks of die bonding processes 300, 800, and 1000 shown and described above in connection with FIGS. 3, 8, and 10, respectively.

At block 1102, a first microelectronic element is provided. The first microelectronic element can have features and properties that are generally similar to the microelectronic element 400 shown in FIG. 4A.

At block 1104, the first microelectronic element can be prepared for direct bonding. As described above in connection with FIGS. 1A and 1B and block 304 of FIG. 3, preparing the microelectronic element for bonding can including polishing the bonding surface of the bonding layer, activating the bonding surface, and/or terminating the bonding surface with a suitable species.

At block 1106, the bow of the first microelectronic element is measured.

At block 1108, a die bow can be calculated based on the measured bow of the first microelectronic element. As described above in connection with FIG. 8 and block 808. Equation 12 can be used to estimate the bow of a thinned and singulated die based at least in part on the measured bow of the pre-singulation, unthinned first microelectronic element, along with the thickness of the unthinned first microelectronic element, the thickness of the die, the width of the unthinned first microelectronic element, and the width of the die.

At block 1110, a die bondability is calculated. In some embodiments, the die bondability can be calculated using the previously described multivariate regression model. In some embodiments, the multivariate regression model can calculate a predicted bondability based at least in part on the calculated die bow (or warpage), the die size, the rigidity of the die, and the stiffness of the die.

At block 1112, whether the calculated die bondability is sufficiently good is determined. In some embodiments, determining whether the calculated die bondability is sufficiently good includes determining whether the calculated die bondability is above a threshold die bondability.

If the calculated die bondability is sufficiently good, the die bonding process 1100 proceeds to block 1114. At block 1114, the first microelectronic element is thinned. In some embodiments, the first microelectronic element can be thinned until it has a predetermined thickness. In some embodiments, the predetermined thickness can be 250 μm or less, 200 μm or less, 150 μm or less, 100 μm or less, 50 μm or less, 20 μm or less, or a value in a range defined by any of these values. As described above in connection with block 306 of FIG. 3 and block 810 of FIG. 8, the first microelectronic element can be thinned by removing material from the back side of the base portion of the microelectronic element grinding away the back side, by etching and/or by CMP of the back side. After thinning the first microelectronic element, at block 1116, the thinned microelectronic element can then be singulated into a plurality of thinned dies and then, at block 1118, at least one of the plurality of thinned dies can be direct bonded to a second microelectronic element.

On the other hand, if the calculated die bondability is not sufficiently good, the die bonding process 1100 proceeds to block 1120 in FIG. 11B. At block 1120, the maximum die bow that still allows for satisfactory bondability is calculated. As described above in connection with block 1020 of FIG. 10, in some embodiments, the die bondability model is used to calculate the maximum die bow that still allows for satisfactory bondability. As with the process of FIG. 10, the calculation of the die bonding process 1100 of FIG. 11 can account not only for die warpage or bow, but also for rigidity and stiffness by way of Equation 1, which in term depend in part on die dimensions. In other embodiments, however, the maximum die bow that still allows for satisfactory bondability is calculated using a different method.

At block 1122, the thickness the stress balancing layer to achieve the maximum die bow is calculated. As described above in connection with block 1022 of FIG. 10, in some embodiments, calculating the thickness of the stress balancing layer to achieve the maximum die bow includes calculating a difference between the maximum die bow and the estimated die bow calculated in block 1108 and the thickness of the stress balancing layer can be calculated using this calculated difference. In some embodiments, there can be a linear relationship between the thickness of the stress balancing layer and the amount of die bow offset by the stress balancing layer. In some embodiments, the relationship between the thickness of the stress balancing layer and the amount of die bow offset by the stress balancing layer can depend on the thickness of the die. In some embodiments, the relationship between the thickness of the stress balancing layer can depend on the amount of die bow, the composition of the die, and/or the die size. Various other factors can also affect the relationship between the thickness of the stress balancing layer and the amount of die bow offset by the stress balancing layer. In some embodiments, thickness of the stress balancing layer to (partially) offset the die bow and ensure that the die has good bondability can be represented by Equations 14 and/or 15. In other embodiments, however, the thickness of the stress balancing layer to (partially) offset expected die bow and ensure that the die has good bondability can be determined using a different equation or process.

At block 1124, the first microelectronic element is thinned. In some embodiments, the first microelectronic element can be thinned until it has a predetermined thickness. In some embodiments, the predetermined thickness can be 250 μm or less, 200 μm or less, 150 μm or less, 100 μm or less, 50 μm or less, 20 μm or less, or a value in a range defined by any of these values. As described above in connection with block 306 of FIG. 3 and block 810 of FIG. 8, the first microelectronic element can be thinned by removing material from the back side of the base portion of the microelectronic element grinding away the back side, by etching and/or by CMP of the back side.

At block 1126, after thinning the first microelectronic element, a stress balancing layer having the thickness calculated in block 1122 is formed on the backside of the thinned first microelectronic element. As described above in connection with block 1026 of FIG. 10, the stress balancing layer can be formed by depositing a dielectric material over the back surface of the thinned first microelectronic element. In some embodiments, forming the stress balancing layer having the calculated thickness includes calculating an amount of dielectric material needed to form the stress balancing layer having the calculated thickness, and then depositing the calculated amount of dielectric material onto the backside of the thinned first microelectronic element. In other embodiments, the stress balancing layer can be formed by depositing the dielectric material onto the back surface of the thinned first microelectronic element until the layer of dielectric material is thicker than the calculated thickness, and then the excess dielectric material can be removed (e.g., by grinding and/or etching the excess dielectric material).

To determine whether the stress balancing layer sufficiently offsets the die bow and that the dies formed from the microelectronic element have good bondability, at block 1128, an updated bow of the thinned first microelectronic element can be measured. At block 1130, an updated expected die bow can be calculated based on the updated bow of the thinned (but still pre-singulation) first microelectronic element having the stress balancing layer on it. For example, in some embodiments, Equation 12 can be used to estimate the updated die bow. In some embodiments, because the thickness of the thinned first microelectronic element having the stress balancing layer on it is substantially equal to the desired thickness of the die, Equation 12 can be simplified as shown below in Equation 16:

$${B}_{2} = {[ \frac{{h}_{1}}{{h}_{2}} ]}^{2} \times {[ \frac{{L}_{2}}{{L}_{1}} ]}^{2} \times {B}_{1} = {[ \frac{{L}_{2}}{{L}_{1}} ]}^{2} \times {B}_{1} \qquad [ 16 ]$$

At block 1132, after calculating the updated die bow using the measured bow of the thinned first microelectronic element having the stress balancing layer formed on it, an updated die bondability is calculated. In some embodiments, the die bondability can be calculated using the previously described multivariate regression model. In some embodiments, the multivariate regression model can calculate a predicted bondability based at least in part on the updated calculated die bow (or warpage), the die size, the rigidity of the die, and the stiffness of the die.

At block 1134, whether the updated die bondability is sufficiently good is determined. In some embodiments, determining whether the calculated die bondability is sufficiently good includes determining whether the calculated die bondability is above a threshold die bondability. In some embodiments, the threshold die bondability can be the same threshold die bondability can be the same threshold die bondability used in block 1112. In some embodiments, determining whether the calculated die bondability is sufficiently good includes comparing the updated die bondability to the die bondability calculated in block 1110.

If the updated die bondability is sufficiently good, the D2W process 1100 proceeds to blocks 1116 and 118 in FIG. 11A, as previously described. On the other hand, if the updated die bondability is not sufficiently good, the D2W process 1100 proceeds back to block 1120 and blocks 1120 through 1134 are repeated. In some embodiments, block 1124 is not performed again such that the first microelectronic element is only thinned once. Repeating blocks 1120 through 1134 (other than block 1124) allows for multiple stress balancing layers to be formed on the microelectronic element as indicated by the iterated calculations to ensure that the dies are sufficiently bondable after additional post-thinning bow measurements. To the extent repeated measurements of wafer bow indicate an earlier iteration overcorrected for expected die bow, block 1126 in successive iterations can involve thinning of the previously formed stress balancing layer, rather than adding to the previously formed stress balancing layer.

In the processes 800, 1000, and 1100 shown in FIGS. 8, 10, and 11, in response to determining that the die bondability is not sufficiently good, a thickness of a stress balancing layer to be deposited is calculated such that the stress balancing layer offsets enough die bow so that the dies have good bondability. In other embodiments, however, in response to determining that the die bondability is not sufficiently good, other aspects of the die formation process can be adjusted to ensure that the dies have good bondability. For example, in some embodiments, the microelectronic element can be thinned to a different thickness than the predetermined thickness. As previously described, the amount of die bow can be at least partially dependent on the final thickness and lateral dimensions of the die, which also affect die rigidity and die stiffness. Accordingly, in some embodiments, in response to determining that the die bondability is not sufficiently good, the microelectronic element can be thinned so that the first microelectronic element has an updated thickness that is different than the predetermined thickness. In embodiments described herein, a stress balancing layer can be formed on the backside of the first microelectronic element and the thickness of the stress balancing layer may be based at least in part on the updated thickness and lateral dimensions of the die to be formed.

In accordance with one aspect, a process of forming a microelectronic device is provided. The process can include preparing a first surface of a first substrate for direct bonding and then thinning the first substrate to form a thinned substrate. The thinned substrate has the first surface and a second surface and the first and second surfaces are on opposing sides of the thinned substrate. The process further includes, after thinning, depositing a stress balancing layer onto the second surface, singulating the thinned substrate to form a plurality of dies, and direct bonding at least one of the plurality of dies to a second substrate.

In some embodiments, each of the plurality of dies includes a portion of the first surface and a portion of the stress balancing layer. In some embodiments, the portion of the first surface includes a first conductive element and a first dielectric portion that surrounds the first conductive element. In some embodiments, the second substrate includes a second conductive element and a second dielectric portion that surrounds the second conductive element and direct bonding the at least one of the plurality of dies to the second substrate includes direct bonding the first conductive element to the second conductive element and direct bonding the first dielectric portion to the second dielectric portion. In some embodiments, the first substrate does not include a TSV. In some embodiments, a portion of the stress balancing layer remains on the at least one of the plurality of dies during direct bonding. In some embodiments, the stress balancing layer includes a dielectric material. In some embodiments, the stress balancing layer includes silicon dioxide (SiO₂). In some embodiments, the first substrate is thinned to have a thickness of about 100 μm or less. In some embodiments, the first substrate is thinned to have a thickness of about 50 μm or less. In some embodiments, the thinned substrate is singulated after depositing the stress balancing layer onto the second surface.

In accordance with another aspect, an apparatus is provided. The apparatus includes a substrate having a first bonding surface and a die. The die includes a second bonding surface on a first side of the die and a backside dielectric layer that forms a second side of the die. The second bonding surface is directly bonded to the first bonding surface, the second side of the die is opposite the first side of the die, and the backside dielectric layer includes an unpatterned dielectric layer.

In some embodiments, the first side of the die includes a plurality of edges defining a perimeter of the first side of the die and the backside dielectric layer does not extend beyond the perimeter of the first side of the die. In some embodiments, the die includes a plurality of side surfaces that extend between the first and second sides of the die and the backside dielectric layer does not contact any of the plurality of side surfaces. In some embodiments, the die includes a first die and the apparatus further includes a second die bonded to the first bonding surface, where the first and second dies are separated from each other by a lateral gap and the backside dielectric layer does not extend into the lateral gap. In some embodiments, the apparatus includes a reconstitution layer formed over the first and second dies, including over the backside dielectric layer of the first die, where the reconstitution layer at least partially fills the lateral gap. In some embodiments, the backside dielectric layer includes silicon dioxide (SiO₂). In some embodiments, the die has a first thickness of about 200 μm or less and the backside dielectric layer has a second thickness of about 10 μm or less. In some embodiments, the first thickness is about 100 μm or less. In some embodiments, the first thickness is about 50 μm or less. In some embodiments, the second thickness is about 5 μm or less. In some embodiments, the die does not include a through-silicon via.

In accordance with another aspect, a method of forming a microelectronic device is provided. The method includes providing a first substrate having a first surface, determining a bow of the first substrate, determining a thickness of a stress balancing layer to be formed based in part on the measured bow, and thinning the first substrate to form a thinned substrate. The thinned substrate includes the first surface and second surface and the first and second surfaces are on opposing sides of the thinned substrate. The method further includes forming the stress balancing layer onto the second surface such that the stress balancing layer has the determined thickness, singulating the thinned substrate into a plurality of dies after forming the stress balancing layer onto the second surface, and direct bonding at least one of the plurality of dies to a second substrate.

In some embodiments, the thinned substrate is singulated into a plurality of dies such that each of the plurality of dies has a die size and wherein determining the thickness of the stress balancing layer to be formed is based in part on the die size. In some embodiments, the method further includes calculating a die bow based in part on the measured bow, where determining the thickness of the stress balancing layer to be formed is based in part on the calculated die bow. In some embodiments, the bow of the first substrate is measured before the first substrate is thinned. In some embodiments, the stress balancing layer includes an inorganic dielectric. In some embodiments, the method further includes determining an amount of dielectric to be deposited based in part on the determined thickness of the stress balancing layer after determining the thickness of the stress balancing layer to be formed, where forming the stress balancing layer onto the second surface includes depositing the determined amount of dielectric onto the second surface.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above.” “below.” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could.” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method of forming a microelectronic device, comprising:
preparing a first surface of a first substrate for direct bonding;
thinning the first substrate to form a thinned substrate, wherein the thinned substrate comprises the first surface and a second surface and wherein the first and second surfaces are on opposing sides of the thinned substrate;
after thinning, depositing a stress balancing layer onto the second surface;
singulating the thinned substrate to form a plurality of dies; and
direct bonding at least one of the plurality of dies to a second substrate.

2. The method of claim 1, wherein each of the plurality of dies comprises a portion of the first surface and a portion of the stress balancing layer.

3. The method of claim 2, wherein the at least one of the plurality of dies comprises a first portion of the first surface that comprises a first conductive element and a first dielectric portion that surrounds the first conductive element, wherein the second substrate comprises a second conductive element and a second dielectric portion that surrounds the second conductive element, and wherein direct bonding the at least one of the plurality of dies to the second substrate comprises direct bonding the first conductive element to the second conductive element and direct bonding the first dielectric portion to the second dielectric portion.

4. (canceled)

5. The method of claim 1, wherein the first substrate does not include a TSV.

6. The method of claim 1, wherein a portion of the stress balancing layer remains on the at least one of the plurality of dies during direct bonding.

7. The method of claim 1, wherein the stress balancing layer comprises a silicon oxide.

8. (canceled)

9. The method of claim 1, wherein thinning the first substrate comprises thinning the first substrate to have a thickness of about 100 μm or less.

10. (canceled)

11. (canceled)

12. An apparatus, comprising:
a substrate having a first bonding surface; and
a die, wherein the die comprises:
a second bonding surface on a first side of the die, wherein the second bonding surface is directly bonded to the first bonding surface; and
a backside dielectric layer that forms a second side of the die, wherein the second side of the die is opposite the first side of the die and wherein the backside dielectric layer comprises an unpatterned dielectric layer.

13. The apparatus of claim 12, wherein the first side of the die comprises a plurality of edges defining a perimeter of the first side of the die and wherein the backside dielectric layer does not extend beyond the perimeter of the first side of the die.

14. The apparatus of claim 12, wherein the die comprises a plurality of side surfaces that extend between the first and second sides of the die and wherein the backside dielectric layer does not contact any of the plurality of side surfaces.

15. The apparatus of claim 12, wherein the die comprises a first die, the apparatus further comprising:
a second die bonded to the first bonding surface, wherein the first and second dies are separated from each other by a lateral gap and wherein the backside dielectric layer does not extend into the lateral gap.

16. The apparatus of claim 15, further comprising:
a reconstitution layer formed over the first and second dies, including over the backside dielectric layer of the first die, wherein the reconstitution layer at least partially fills the lateral gap.

17. (canceled)

18. The apparatus of claim 12, wherein the die has a first thickness of about 200 μm or less and the backside dielectric layer has a second thickness of about 10 μm or less.

19. The apparatus of claim 18, wherein the first thickness is about 100 μm or less.

20. (canceled)

21. (canceled)

22. The apparatus of claim 12, wherein the die does not include a through-silicon via.

23. A method of forming a microelectronic device, comprising:
providing a first substrate having a first surface;
determining a bow of the first substrate;
determining a thickness of a stress balancing layer to be formed based in part on the measured bow;
thinning the first substrate to form a thinned substrate, wherein the thinned substrate comprises the first surface and second surface and wherein the first and second surfaces are on opposing sides of the thinned substrate;
forming the stress balancing layer onto the second surface such that the stress balancing layer has the determined thickness;
after forming the stress balancing layer onto the second surface, singulating the thinned substrate into a plurality of dies; and
direct bonding at least one of the plurality of dies to a second substrate.

24. The method of claim 23, wherein singulating the thinned substrate into a plurality of dies comprises singulating the thinned substrate into a plurality of dies such that each of the plurality of dies has a die size and wherein determining the thickness of the stress balancing layer to be formed is based in part on the die size.

25. The method of claim 23, further comprising:
calculating a die bow based in part on the measured bow, wherein determining the thickness of the stress balancing layer to be formed is based in part on the calculated die bow.

26. (canceled)

27. The method of claim 23, wherein the stress balancing layer comprises an inorganic dielectric.

28. The method of claim 23, further comprising:
after determining the thickness of the stress balancing layer to be formed, determining an amount of dielectric to be deposited based in part on the determined thickness of the stress balancing layer, wherein forming the stress balancing layer onto the second surface comprises depositing the determined amount of dielectric onto the second surface.
